(19) United States
(12) Patent Application Publication
(10) Pub. No.: US 2007/0145549 A1
(43) Pub. Date: Jun. 28, 2007

(54) Hermetically sealed integrated circuits and method

(75) Inventor: H. Jerome Barber, Tucson, AZ (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/316,765

(22) Filed: Dec. 23, 2005

(51) Int. Cl. H01L 23/02

(52) U.S. Cl. 257/678; 438/106

(57) ABSTRACT

A semiconductor device includes an integrated circuit die, wherein a layer of photoresist is permanently disposed on and permanently hermetically seals an active circuit area of a top surface of the inductor die. In one embodiment, the semiconductor device includes a lead frame including a conductive pad and a plurality of conductive leads, wherein the die is attached to the conductive pad, and wherein bonding wires bond the leads of the lead frame to bonding pads of the die, and wherein the die and bonding wires are encapsulated in package material. In another embodiment, solder bumps are provided on the bonding pads, and the die is inverted and the solder bumps are attached to corresponding conductors on a printed circuit board.

### BACKGROUND OF THE INVENTION

The present invention relates generally to a new integrated circuit structure and a method for providing hermetic sealing of integrated circuit chips, including chips assembled in plastic packages.

Hermetic sealing for integrated circuits is important for maintaining the electrical characteristics of circuit elements, including thin film resistors, in the presence of moisture. Ingression of moisture can change the resistances of thin film resistors and render them inoperable. Ingression of moisture is one of the causes of corrosion of interconnect metal and dissolution of thin film resistor material.

In the past, various kinds of hermetic passivation layers, such as silicon nitride layers, silicon oxy-nitride layers, and silicon carbide layers, have been provided on the top surfaces of integrated circuit chips. These hermetic passivation layers hermetically seal the active regions of the semiconductor chips, but unfortunately also tend to adversely affect the “high-grade yields” of analog products as a result of increased stresses imposed by the passivation layers on the surfaces of the integrated circuit chips. (The term “high-grade yield” refers to tightened specifications for “premium” integrated circuits, which command premium market prices. Integrated circuits which fail to meet the high-grade yield specifications nevertheless may pass lower “commercial part” specifications, which command lower market prices.)

SiO2 layers are commonly used as passivation layers on integrated circuits, and provide substantially improved manufacturing yields. However, integrated circuit chips with SiO2 passivation layers are not hermetic when they are packaged in conventional plastic packages.

Polyimide films have been utilized on semiconductor chips to reduce stress in the active circuit regions of the integrated circuit chips and, if sufficiently thick, can absorb and resist moisture enough to provide hermetic sealing. Some polyamide films are imageable, but they are much more expensive than conventional photoresist films, and using them adds additional complexity to the integrated circuit manufacturing process. For example, a special polyimide film coating track must be set up with its soft bake temperature adjusted. This track must be cleaned and maintained regularly, and can not be shared with a photoresist track. A special soft bake oven may have to be installed because of the elevated bake temperature required prior to exposure of the polyimide. A special developing program must be created and maintained. The cure process for imageable polyimide coating usually is performed in a diffusion furnace at a temperature which is much higher than is used for curing photoresist. The process for using imageable polyimide requires more equipment, more maintenance, more engineering, and hence much more cost than for processes using photoresist.

Integrated circuit chips having typical oxide passivation usually fail HAST testing (Highly Accelerated Stress Test Testing) within less than five hours. The HAST testing is performed at 130 degrees Centigrade for 96 hours in the presence of ambient atmosphere having a relative humidity of 85%, with all of the integrated circuits under test being electrically biased. The weakest parts of a semiconductor package with respect to its ability to provide hermetic sealing against moisture are the interface regions between the packaging material and the package leads where they extend through the package wall. External moisture tends to migrate along the leads in the interface regions and along the bonding wires to the bonding pads of the integrated circuit chip. The moisture then tends to migrate from the bonding pads into active circuit regions of the chip surface, where the moisture is likely to cause dissolution of thin film resistors and hence cause shifts in their electrical characteristics, and possibly cause catastrophic failure of the integrated circuit chip. Integrated circuit chips that do not have hermetic passivation and which are packaged in non-hermetic packages therefore are likely to fail if the non-hermetic package is exposed to moisture.

For example, if integrated circuit chips having oxide passivation are placed into plastic packages without encapsulation such that the integrated circuitry is directly exposed to the ambient environment, and the chips then are placed in an environmental chamber to test them for hermetic sealing against moisture, such integrated circuit chips typically fail even before the chip temperature reaches the specified test level as the environmental chamber temperature is being ramped up to a specified test level.

Non-hermetic sealing is especially problematic with plastic-encapsulated, oxide-passivated integrated circuits, which typically fail in less than a usual 96 hour testing period. Also, the presence of moisture which has ingressed to the integrated circuit chips may cause other electrical problems, such as corrosion of the interconnect metallization of the integrated circuit chips, and may also cause sufficient corrosion of the bonding pad metallization on the chips to allow the wire bonds to separate from the bonding pads. In most cases the plastic encapsulating material alone does not provide a reliable hermetic sealing of packaged integrated circuit die, especially in smaller plastic packages in which the shorter bonding wires permit moisture to migrate to the bonding pads and into the active circuitry much more quickly than is the case for larger plastic packages with substantially longer wire bonds.

Since oxide passivating layers do not provide hermetic sealing of the active circuit regions of the integrated circuit chips, the only practical way of obtaining hermetic sealing for integrated circuit chips with oxide passivation is to assemble them in hermetic packages. Unfortunately, available hermetic packages are much more expensive than plastic packages.

There is an unmet need for an improved, hermetically sealed integrated circuit and method.

There also is an unmet need for an inexpensive method for providing hermetically sealed integrated circuit chips.

There also is an unmet need for an inexpensive method for providing integrated circuit devices wherein the integrated circuit chips are hermetically sealed even though they are packaged in non-hermetic packages.

There also is an unmet need for an inexpensive method for providing un-packaged hermetically sealed integrated circuit chips for flip-chip applications and the like.

There also is an unmet need for a technique for providing hermetically sealed integrated circuit chips in a way that does not disrupt conventional integrated circuit chip processing and packaging procedures.

### SUMMARY OF THE INVENTION

It is an object of the invention to provide an improved hermetically sealed integrated circuit and method.

It is another object of the invention to provide an inexpensive method for providing hermetically sealed integrated circuit chips.

It is another object of the invention to provide an inexpensive method for providing integrated circuit devices in which the integrated circuit chips are effectively hermetically sealed even if they are packaged in non-hermetic packages.

It is another object of the invention to provide an inexpensive method for providing un-packaged hermetically sealed integrated circuit chips for flip-chip applications and the like.

It is another object of the invention to provide an inexpensive method for providing hermetically sealed integrated circuit chips without disrupting conventional integrated circuit chip processing and packaging procedures.

Briefly described, and in accordance with one embodiment, the present invention provides a semiconductor device (1) including a semiconductor die (2), a plurality of bonding pads (7A-7H) located adjacent to an active circuit area (20) of the semiconductor die (2), a permanent layer of hermetically sealing photoresist (8) disposed on a top surface of the semiconductor die (2), and a plurality of bonding pad openings (9A-9H) extending through the layer of hermetically sealing photoresist (128) to expose the plurality of bonding pads (7A-H), respectively. In one embodiment, the semiconductor device includes a lead frame (3) which has a plurality of conductive leads (3A-H) and a conductive pad (3J) to which the semiconductor die (2) is attached, wherein a plurality of bonding wires (4A-H) bonds the leads (3A-H) to the bonding pads (7A-H), respectively. Package material (10) surrounds the conductive pad (3J) and the semiconductor die (2), wherein inner portions of the conductive leads (3A-H) extend through and beyond the package material (10). In one embodiment, the package material includes molded plastic. In the described embodiments, the layer of photoresist (8) has very low contaminant levels, of less than several parts per billion.

In one embodiment, the semiconductor die (2) is a flip-chip having solder bumps (18A-C) on the bonding pads (7A-7H), wherein the solder bumps extended outward beyond the layer of photoresist (8) and are adapted to be attached to corresponding conductors of a printed circuit board (14).

In one embodiment, the invention provides a method of hermetically sealing an integrated circuit die (2), wherein the integrated circuit die (2) includes a plurality of bonding pads (7A-7C) adjacent to an active circuit area (20) of the integrated circuit die (2), the integrated circuit die (2) also including a passivation layer (11) having bonding pads openings (9A-9H) exposing the bonding pads (7A-7C), wherein the method includes coating a top surface of the integrated circuit die (2) with a layer of photoresist (8), exposing portions of the layer of photoresist (8) over the bonding pads to light, etching away the exposed portions of the layer of photoresist (8) to expose the bonding pads, and curing the layer of photoresist (8), the layer of photoresist (8) permanently remaining on the integrated circuit die (2) and providing hermetic sealing of the active circuit area (20). The integrated circuit die (2) is included in a wafer, the method including performing a dehydration bake cycle on the wafer and then providing an adhesion-promoting substance on the wafer before the depositing the layer of photoresist (8). A post-exposure bake cycle is performed on the wafer before a photographic developing process. The photographic developing process is followed by a hard bake cycle after the post-exposure bake cycle. A deep UV cure process is performed to stabilize the layer of photoresist (8).

### BRIEF DESCRIPTION OF THE DRAWINGS

FIG. 1 is a plan view diagram of a semiconductor chip wire bonded to a lead frame and having on its top surface a permanent layer of photoresist which hermetically seals the chip from moisture.

FIG. 2 is a section view along section line 2-2 of FIG. 1.

FIG. 3 is a section view illustrating a mounted flip-chip having on its active surface a layer of photoresist to provide hermetic sealing of the chip.

### DETAILED DESCRIPTION OF THE PREFERRED EMBODIMENTS

The present invention provides a simple, inexpensive way of hermetically sealing integrated circuit chips without requiring substantial modification of conventional semiconductor wafer processing procedures or conventional integrated circuit chip packaging procedures.

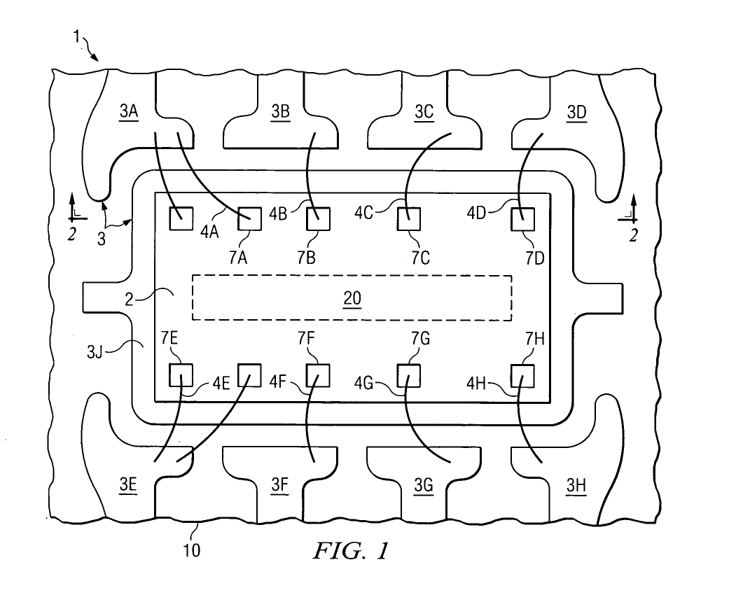

FIG. 1 shows an image that would appear in a plan view X-ray radiograph of a packaged integrated circuit 1 which incorporates the present invention. Packaged integrated circuit 1 includes an integrated circuit die 2 (i.e., chip 2) and a lead frame 3. Lead frame 3 includes a lead frame pad 3J and a plurality of leads 3A-3H. Integrated circuit die 2 is die-attached to lead frame pad 3J. A plurality of bonding pads 7A-7H of chip 2 are bonded by means of bonding wires 4A-4H to leads 3A-3H, respectively.

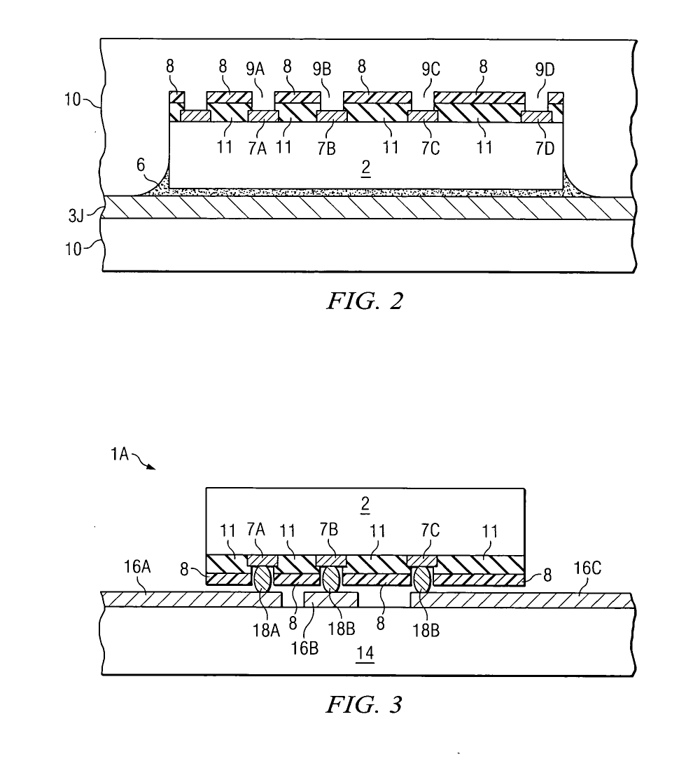

FIG. 2 shows a partial section view taken along section line 2-2 of FIG. 1. Referring to FIG. 2, silicon chip 2 is die-attached by means of conventional die attach material 6 to lead frame pad 3J. An oxide passivation layer 11 is deposited as the final passivation layer on a semiconductor wafer in which integrated circuit chips such as chip 2 are formed. Using conventional photolithography procedures, a coat of photoresist (not shown) is spun onto oxide passivation layer 11, and then is exposed to suitable light using a suitable photomask which corresponds to the desired bonding pad openings 9A-9H extending through oxide passivation layer 11 to the corresponding bonding pads 7A-7H, respectively. The photoresist layer then is developed.

The next step is to etch the desired bonding pad openings 9A-9H through oxide passivation layer 11 so that bonding pads 7A-7H are un-covered. The remaining photoresist utilized in the foregoing patterning of the bonding pad openings 9A-9H then is stripped.

The wafer then is subjected to electrical probing of the bonding pads 7A-7H in order to test the integrated circuit chips of the wafer. Individual “reject” die which do not pass the electrical test procedure may be inked at this time or later to identify them. (The reject die also may be identified on a wafer map.)

In accordance with the present invention, a permanent “overcoat” layer 8 of conventional photoresist is provided on the standard final oxide passivation layer 11 of integrated circuit chip 2 after the electrical probe testing of chip 2 (by using conductive probes to contact the various bonding). Permanent overcoat photoresist layer 8 performs the function of hermetically sealing integrated circuit chip 2 from moisture and other contaminants.

The procedure for providing permanent overcoat photoresist layer 8 is as follows. After the electrical probe test procedures are complete, the process of making the integrated circuit chip 2 according to the present invention includes subjecting the wafer to an ash-strip oxygen plasma cleaning procedure at approximately 200 degrees Centigrade for approximately 90 seconds.

Then a conventional adhesion-promoting chemical, such as HMDS (hexamethyl disilazane), is vapor deposited onto the wafer surface in a vapor prime oven in a conventional manner to provide hydrogen bonds to which overcoat photoresist layer 8 can chemically bond.

Next, the wafer surface is coated with “overcoat” photoresist. The particular photoresist used by the applicant is SPR 3625 or SPR 3612 photoresist, available from Shiply Corp., which is now owned by Rohm and Haas. The coat of overcoat photoresist then is spun onto the wafer to form overcoat photoresist layer 8. The bonding pad openings 9A-9H are aligned with a suitable photomask, and then the layer of overcoat photoresist 8 is exposed to suitable light. Next, a post-exposure bake is performed at approximately 110 degrees Centigrade for approximately 60 seconds, in order to stabilize the photoresist and provide it with more stable side walls.

It should be noted that only the portions of photoresist overcoat layer 8 over the bonding pad areas and the scribe grid areas of the wafer are exposed. It should also be noted that an increase in exposure energy is necessary to clean out the somewhat thicker photoresist in the bond pad openings 9A-9H, including where there are probe marks on the bonding pads 7A-7H caused by the prior electrical probe testing.

Then overcoat photoresist layer 8 is developed. The foregoing exposure of the photoresist over bonding pads 7A-7H causes the exposed photoresist to become acidic when it is then developed by subjecting it to a developer. An aqueous base solution of TMAH (tetramethyl ammonium hydroxide) can be used as the developer.

The thickness of overcoat photoresist layer 8 typically is about 3 microns, although it could easily be in the range from 1-4 microns, depending on the spin speed and viscosity of the overcoat photoresist material. (Note that either positive photoresist or negative photoresist can be used. There are usually more contaminants in negative photoresist than in positive photoresist, but negative photoresist typically is more thermally stable than positive photoresist and could probably withstand temperatures approaching 300 degrees Centigrade after curing. It is desirable to select a low-contamination photoresist material. Low-contamination photoresist is readily commercially, and its levels of contamination by, for example, sodium, potassium, calcium, iron, and/or a few other metals, are available from the photoresist specifications. The above-mentioned photoresist used by the applicant contains contaminant levels of only a few parts per billion.)

The next step is to perform a post-exposure “soft” bake at a temperature of 110 degrees Centigrade for approximately 60 seconds, to “set” the resist and drive out some of the solvents therein. Then an additional “hard” dehydration bake is performed at 145 degrees Centigrade for approximately 30 minutes to drive out more moisture in overcoat photoresist layer 8 to get it ready for a DUV (deep ultraviolet) cure.

The deep UV (ultraviolet) cure is performed by slowly ramping the chip temperature up to approximately 175 degrees Centigrade and maintaining that temperature with the deep UV lamp at high intensity for approximately 93 seconds in order to cure overcoat photoresist layer 8 so that solvents therein do not out-gas during subsequent assembly operations. The deep UV cure also is necessary to ensure that the overcoat photoresist layer 8 is stable enough that it doesn't flow at higher subsequent assembly temperatures. After the above mentioned deep UV cure has been performed, the subsequent assembly temperatures can be as high as 265 degrees Centigrade without damaging overcoat photoresist layer 8.

If die which failed the above-mentioned electrical test were not inked prior to the deposition of overcoat photoresist layer 8, they can be inked at this point in the process. (If wafer maps have been used to locate the die which passed the electrical test, then inking is optional.)

The packaging steps that are subsequently performed to provide the structure shown in FIGS. 1 and 2, including die attaching, wire bonding, and encapsulation procedures, all are conventional. Package encapsulation material 10, which can be injection molded plastic, encapsulates integrated circuit chip 2 with permanent overcoat photoresist layer 8, lead frame 3J, and the inner portions of leads 3A-3H, whereby the outer end sections of leads 3A-3H extend beyond the encapsulation material 10. The assembly process can reach temperatures of up to approximately 260 degrees Centigrade for a short time (typically is less than 1 minute). The overcoat photoresist layer 8 must be stable, i.e., not flowable, up to this temperature to ensure that the die attachment and the package sealing are reliable.

The HAST (Highly Accelerated Stress Testing) stress testing of high-grade analog integrated circuit chips made according to the present invention, in an open cavity package with aluminum wire bonds connected to the aluminum bonding pads, resulted in no functional chip failures during more than 400 hours of testing at 135 degrees Centigrade in the presence of ambient atmosphere having a relative humidity of 85%. Experiments using both positive photoresist and negative permanent photoresist layers 8 on typical oxide passivation were performed with similar results.

Analysis of integrated circuit chips made in accordance with the invention, tested under open-cavity conditions for 400 hours at 135 degrees Centigrade in the presence of an 85% relative humidity ambient, and then subjected to standard shock tests resulted in no device failures.

It is noteworthy that when a conventional passivation etch process is performed to form the bonding pad openings 9A-9H through the final passivation oxide (to allow wire bonding to the bonding pads), the photoresist flows slightly over the edge of the oxide passivation and rests on the bonding pad metallization. (It is not possible to wire bond through the photoresist.) This forms a hermetic seal between the passivation and the peripheral portion of bonding pad and prevents any moisture that succeeds in migrating along the leads and bonding wires to the bonding pads of a non-hermetic package from then ingressing or migrating under the passivation oxide and then damaging the circuitry.

Overcoat photoresist layer 8 also provides the benefit of protecting the final passivation oxide layer 11 from damage and from debris which can simply be blown off with a puff of gas. When the wafers are scribed or sawn into individual chips by a scribe saw in the conventional manner, usually a slurry of silica dust spreads over the wafer surface. The photoresist layer 8 prevents the silica dust from accumulating and allows it to be washed away from the die surface by cooling water that is sprayed on the saw blade so that the saw debris do not result in damage during subsequent handling of the chips.

Thus, the present invention solves the previously mentioned problems associated with non-hermetic passivation, such as oxide passivation layer 11, on integrated circuit chips in plastic packages by using permanent overcoat photoresist layer 8 on top of an oxide or other type of final passivation layer. Permanent overcoat photoresist layer 8 has been found to prevent the above-mentioned moisture attack on thin film resistors and other components of integrated circuit chips packaged in plastic packages. The use of permanent overcoat photoresist layer 8 has been shown to not adversely affect the high-grade yields associated with oxide-passivated analog integrated circuits.

Another benefit of overcoat photoresist layer 8 is that it tends to provide stress relief along the surface of the active layer of semiconductor chip 2. This is because stress due to the underlying passivation oxide 11 on the active area of the chip 2 is compressive stress, whereas a tensile stress is produced by overcoat photoresist layer 8 on the underlying passivation oxide 11 as a result of the heat treatment to which it is subjected. The tensile stress of overcoat photoresist layer 8 therefore tends to reduce or cancel the compressive stress produced along the surface of the active circuit area by the passivation oxide 11. This cancellation is desirable because the presence of stress in the active regions of the integrated circuit chip can undesirably affect circuit performance after degrading occurs in circuit parameters (such as the current gain β of bipolar transistors, resistance values of thin film resistor values, and offset voltages) associated with differentially coupled transistors.

Another advantage of the method of the present invention is that it does not require use of any new chemicals in a wafer fabrication facility. Also, improved hermetic sealing of integrated circuits in plastic packages is achieved without degrading the previously mentioned “high-grade yield” of integrated circuits.

It should be noted that overcoat photoresist layer 8 could be applied either before or after wafer probe testing operations and that reject die which have failed electrical probe testing can be inked either before or after overcoat photoresist layer 8 is formed. Overcoat photoresist layer 8 could be spun on or sprayed on, in which case the spun-on or sprayed-on overcoat photoresist layer 8 would extend over the edges of the bonding pad openings and cover the peripheral edge portions of the bonding pads, and the assembly than could be baked to cure photoresist layer 8. The package seal then could be accomplished in a conventional way. It also should be noted that overcoat photoresist layer 8 can be used to hermetically seal integrated circuit chips that are not packaged.

FIG. 3 shows a sectional view of a flip-chip structure 1A including integrated circuit chip 2 and a printed circuit board 14. Integrated circuit chip 2 includes the same overcoat photoresist layer 8 as shown in FIG. 2, but chip 2 in FIG. 2 is not encapsulated in packaging material 10 as in FIG. 2, and bonding pads 7A-7H are not wire bonded to package leads. Instead, conventional solder bumps, such as solder bumps 7A-7C shown in FIG. 3, are formed on bonding pads 7A-7H, respectively. Integrated circuit chip 2 then is inverted or “flipped”, and the solder bumps, which extend beyond the bonding pad openings in overcoat photoresist layer 8, are physically and electrically attached to corresponding printed circuit board conductors such as conductors 16A, 16B, and 16C in FIG. 3.

Thus, the efficacy of the invention is essentially the same irrespective of what kind of cavity or encapsulation material is used to contain the chip.

While the invention has been described with reference to several particular embodiments thereof, those skilled in the art will be able to make various modifications to the described embodiments of the invention without departing from its true spirit and scope. It is intended that all elements or steps which are insubstantially different from those recited in the claims but perform substantially the same functions, respectively, in substantially the same way to achieve the same result as what is claimed are within the scope of the invention. For example, in some cases it would be possible to provide the permanent photoresist layer 8 on the chip directly over a metallization layer. The exact materials, temperatures, and times used in the above description of the invention are not critical, and those skilled in the art will be able to vary them and still obtain the benefit of the invention.

What is claimed is:

1. A semiconductor device, comprising:
(a) a semiconductor die;
(b) a plurality of bonding pads adjacent to an active circuit area of the semiconductor die;
(c) a permanent layer of hermetically sealing photoresist disposed on a top surface of the semiconductor die; and
(d) a plurality of bonding pad openings extending through the layer of hermetically sealing photoresist to expose the plurality of bonding pads, respectively.

2. The semiconductor device of claim 1 including a lead frame which includes a plurality of conductive leads and a conductive pad, the semiconductor die being attached to the conductive pad, a plurality of bonding wires bonding the conductive leads to the bonding pads, respectively.

3. The semiconductor device of claim 2 including package material surrounding the conductive pad and the semiconductor die, wherein inner portions of the conductive leads extend through and beyond the package material.

4. The semiconductor device of claim 3 wherein the package material includes plastic.

5. The semiconductor device of claim 1 wherein the layer of hermetically sealing photoresist covers substantially the entire top surface of the semiconductor die except the bonding pad openings and a scribe grid area.

6. The semiconductor device of claim 1 wherein the layer of hermetically sealing photoresist is positive photoresist.

7. The semiconductor device of claim 1 wherein the semiconductor die is a flip-chip having solder bumps on the bonding pads, the solder bumps extending outward beyond the layer of hermetically sealing photoresist and adapted to be attached to corresponding conductors of a printed circuit board.

8. The semiconductor device of claim 3 wherein the packaging material provides a non-hermetic seal between the semiconductor die and an outside atmosphere.

9. A method of hermetically sealing an integrated circuit die, the integrated circuit die including a plurality of bonding pads adjacent to an active circuit area of the integrated circuit die, the integrated circuit die also including a passivation layer having bonding pad openings therein exposing the bonding pads, the method comprising:
(a) coating a top surface of the integrated circuit die with a layer of photoresist;
(b) exposing portions of the layer of photoresist at least over the bonding pads to light;
(c) etching away the exposed portions of the layer of photoresist, to expose at least the bonding pads; and
(d) curing the layer of photoresist, the layer of photoresist permanently remaining on the integrated circuit die and providing hermetic sealing of the active circuit area.

10. The method of claim 9 wherein the integrated circuit die is included in a wafer, the method including performing a dehydration bake cycle on the wafer and then providing an adhesion-promoting substance on the wafer before step (a).

11. The method of claim 10 including performing a soft bake cycle on the wafer after step (a).

12. The method of claim 11 including exposing portions of the layer of photoresist over the bonding pads to light of a predetermined wavelength, intensity, and duration after the soft bake cycle.

13. The method of claim 12 including performing a post-exposure bake cycle on the wafer.

14. The method of claim 13 including performing a photographic developing process on the layer of photoresist after the post-exposure bake cycle.

15. The method of claim 14 including performing a hard bake cycle on the wafer after the photographic developing process to dry the top surface of the semiconductor die.

16. The method of claim 15 including performing an additional dehydration bake cycle to prevent blistering of thin film resistor material during a subsequent deep UV (ultraviolet) cure process.

17. The method of claim 16 including performing the deep UV cure process to stabilize the layer of photoresist.

18. The method of claim 15 wherein the hard bake is performed at approximately 145 degrees Centigrade for approximately 30 minutes.

19. The method of claim 9 including attaching the integrated circuit die to a conductive pad of a lead frame by means of die attach material, and wire bonding a plurality of bonding pad sites on the top surface of the integrated circuit die to a plurality of leads of the lead frame, respectively.

20. An integrated circuit die made by the process comprising:
(a) providing a plurality of bonding pads adjacent to an active circuit area of the integrated circuit die;
(b) providing a passivation layer having bonding pads openings therein exposing the bonding pads;
(c) coating the integrated circuit die with a layer of photoresist on the passivation layer and the bonding pads;
(d) exposing portions of the layer of photoresist over the bonding pads to light;
(e) etching away the exposed portions of the layer of photoresist to expose the bonding pads; and
(f) curing the layer of photoresist, the layer of photoresist permanently remaining on the integrated circuit die and providing hermetic sealing of the active circuit area.
